(19) United States
(12) Patent Application Publication
(10) Pub. No.: US 2020/0286765 A1
(43) Pub. Date: Sep. 10, 2020

(54) METHODS AND SYSTEMS FOR ALIGNMENT TO EMBEDDED PATTERNS IN SEMICONDUCTOR DEVICE PROCESSING

(71) Applicant: Alta Devices, Inc., Sunnyvale, CA (US)

(72) Inventors: Borirak OPASANONT, Santa Clara, CA (US); Abraham SALDIVAR-VALDES, Redwood City, CA (US); Daniel G. PATTERSON, Morgan Hill, CA (US)

(21) Appl. No.: 16/809,911

(22) Filed: Mar. 5, 2020

Related U.S. Application Data
(60) Provisional application No. 62/815,185, filed on Mar. 7, 2019.

(51) Int. Cl. H01L 21/68; H01L 21/66; H01L 23/544

(52) U.S. Cl. CPC H01L 21/681; H01L 2223/54426; H01L 23/544; H01L 22/20

(57) ABSTRACT

Aspects of the present disclosure include methods, apparatuses, and computer readable media for emitting an incident light toward a semiconductor layer of a semiconductor device, wherein the incident light is a sub-bandgap light substantially transparent to the semiconductor layer, detecting a reflected light generated from the incident light penetrating through the semiconductor layer of the semiconductor device and reflecting off of a portion of the semiconductor device, identifying a macroscopic feature underneath the semiconductor layer based on the reflected light, wherein the macroscopic feature corresponds to the portion of the semiconductor device and is visible to the naked eye, and performing an alignment procedure by using the identified macroscopic feature as a reference for the alignment procedure.

### CROSS-REFERENCE TO RELATED APPLICATIONS

The current application claims the benefit of U.S. Provisional Application No. 62/815,185, filed on Mar. 7, 2019, entitled “METHODS AND SYSTEMS FOR ALIGNMENT TO EMBEDDED PATTERNS IN SEMICONDUCTOR DEVICE PROCESSING,” the contents of which are incorporated by reference in their entireties.

### BACKGROUND

Traditional pattern alignment in semiconductor device processing requires imaging the pattern on the device surface with visible light illumination. In the case where the device surface has no visible patterns, fiducials are created, commonly outside of the active device area to aid alignment across multiple processing steps. Such approach requires adding a processing step to create the fiducials. Fiducials may be alignment markers and/or references added for the purposes of alignment. Fiducials may be added on the back of a semiconductor device, in-between components, on carriers, and/or along the cleave lines. If fiducials are used in order to aid alignment to an embedded pattern or on the backside, then tolerance stacking could be a problem.

While visible light may be used for alignment, using visible light may require high resolution cameras because the sizes of the fiducials are limited (e.g., microscopic). Further, high resolutions cameras may have small fields of view, which may extend the amount of time searching for the fiducials because small fields of view may only search small areas of the semiconductor device.

For large semiconductor devices, alignment may increase the manufacturing costs significantly due to decreased yield and/or longer manufacturing time. In order to keep the cost low and yield high, improvement in the alignment process may be desirable.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In certain implementations, a method according aspects of the current disclosure makes use of sub-bandgap light to illuminate through the semiconductor device, and a detector (e.g., camera) sensitive to the wavelength of the sub-bandgap light to image the pattern. The incident angle of the light may be adjusted such that reflection from the embedded pattern of the semiconductor device is collected into the imaging device, but the primary specular reflection may not be collected (i.e. dark-field imaging). The method works well in the case where the embedded pattern has a sloped edge.

A system may include an imaging device (such as camera) and a sub-bandgap light source. The light source angle relative to camera may be adjusted so that illumination is reflected off of the pattern edge. The camera may be mounted perpendicular to the device surface. The light source may be mounted at a narrow angle (i.e. high) from the camera, so as to capture reflection off of one or more small slopes in the embedded pattern. A low angle light source may be used for high-aspect ratio patterns.

The system may be incorporated onto a processing tool to aid device alignment. The system may further include of a pattern-recognition software to detect pattern within imaging field of view, a computer to compute offsets and rotation, and/or a moving stage to adjust position of the device to achieve alignment.

Aspects of the present disclosure include methods for emitting an incident light toward a semiconductor layer of a semiconductor device, wherein the incident light is a sub-bandgap light substantially transparent to the semiconductor layer, detecting a reflected light generated from the incident light penetrating through the semiconductor layer of the semiconductor device and reflecting off of a portion of the semiconductor device, identifying a macroscopic feature underneath the semiconductor layer based on the reflected light, wherein the macroscopic feature corresponds to the portion of the semiconductor device and is visible to the naked eye, and performing an alignment procedure by using the identified macroscopic feature as a reference for the alignment procedure.

Other aspects of the present disclosure include an alignment system including a stage, one or more light sources configured to emit an incident light toward a semiconductor layer of a semiconductor device positioned on the stage, wherein the incident light is a sub-bandgap light substantially transparent to the semiconductor layer, a detector configured to detect a reflected light generated from the incident light penetrating through the semiconductor layer of the semiconductor device and reflecting off of a portion of the semiconductor device, an optical controller configured to identify a macroscopic feature underneath the semiconductor layer based on the reflected light, wherein the macroscopic feature corresponds to the portion of the semiconductor device and is visible to the naked eye, and a stage controller configured to perform an alignment procedure by using the identified macroscopic feature as a reference for the alignment procedure.

An aspect of the present disclosure includes an alignment system including means for emitting an incident light toward a semiconductor layer of a semiconductor device, wherein the incident light is a sub-bandgap light substantially transparent to the semiconductor layer, means for detecting a reflected light generated from the incident light penetrating through the semiconductor layer of the semiconductor device and reflecting off of a portion of the semiconductor device, means for identifying a macroscopic feature underneath the semiconductor layer based on the reflected light, wherein the macroscopic feature corresponds to the portion of the semiconductor device and is visible to the naked eye, and means for performing an alignment procedure by using the identified macroscopic feature as a reference for the alignment procedure.

Some aspects of the present disclosure include non-transitory computer readable media having instructions stored therein that, when executed by one or more processors of a control system, cause the one or more processors to perform the steps of causing one or more light sources to emit an incident light toward a semiconductor layer of a semiconductor device, wherein the incident light is a sub-bandgap light substantially transparent to the semiconductor layer, detect a reflected light generated from the incident light penetrating through the semiconductor layer of the semiconductor device and reflecting off of a portion of the semiconductor device, identify a macroscopic feature underneath the semiconductor layer based on the reflected light, wherein the macroscopic feature corresponds to the portion of the semiconductor device and is visible to the naked eye, and perform an alignment procedure by using the identified macroscopic feature as a reference for the alignment procedure.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is a diagram of a semiconductor device;

FIG. 2 is another diagram of a semiconductor device;

FIG. 3 is a schematic diagram of an example of an alignment system according to aspects of the present disclosure;

FIG. 4 is a schematic diagram of an example of a computer system for implementing the alignment system;

FIG. 5 are examples of images detected by the detector;

FIG. 6 is an example of the alignment system according to aspects of the present disclosure; and

FIG. 7 is a process flow diagram of an example of process alignment.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

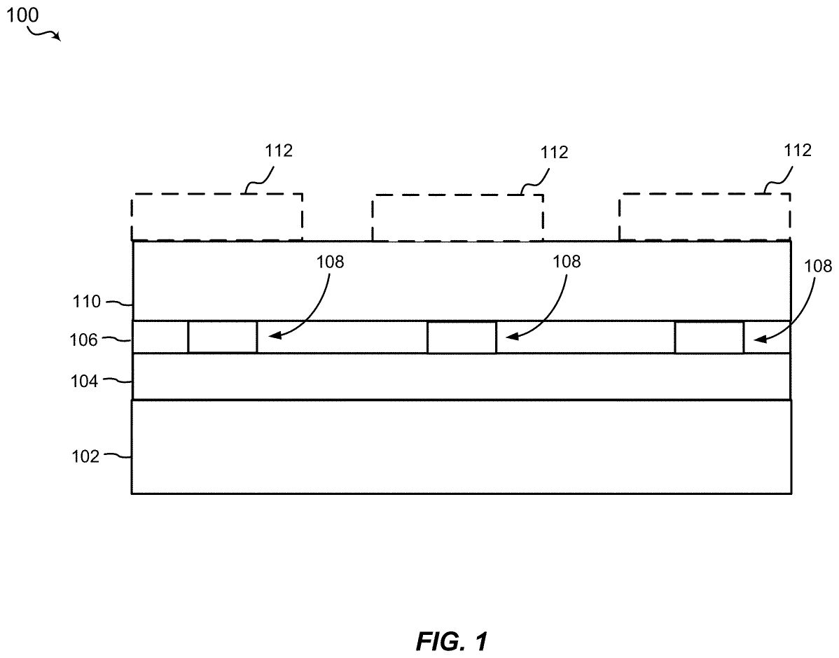

Referring to FIG. 1, in certain aspects, a semiconductor device 100 may be a solar cell (also referred to as photovoltaic (PV) devices), a light emitting device, or other optical semiconductor device. The semiconductor device 100 may include an optional carrier 102. The carrier 102 may be a heavily doped (P-type or N-type) silicon substrate, an intrinsic silicon substrate, an oxidized silicon substrate, a glass substrate, a sapphire substrate, or other substrates. The size (edge or diameter) carrier 102 may be 1 inch, 2 inches, 4 inches, 6 inches, 10 inches, 12 inches, 15 inches, or other sizes. The semiconductor device 100 may include one or more bottom electrodes 104. The one or more bottom electrodes 104 may include silver, gold, palladium, platinum, or other elemental metal materials or alloys. The one or more bottom electrodes 104 may include a carrier transport layer, a carrier injection layer, and/or a carrier extraction layer.

In some implementations, the semiconductor device 100 may include a dielectric layer 106 having one or more vias 108. The one or more vias 108 may be created by selectively etching (dry or wet etching following a photolithography patterning) a portion of the dielectric layer 106.

In some aspects of the present disclosure, the semiconductor device 100 may include a semiconductor layer 110. The semiconductor layer 110 may be a light absorbing semiconductor, such as gallium arsenide, gallium arsenide phosphide, gallium phosphide, aluminum gallium arsenide, aluminum gallium nitride, aluminum gallium indium phosphide, aluminum gallium indium nitride, aluminum gallium, aluminum phosphide, aluminum nitride, zinc selenide, indium gallium nitride, indium gallium arsenide, silicon carbide, or other elemental, molecular (e.g., II-VI or III-V compounds), or organic semiconductors. In some examples, the one or more bottom electrodes 104 may contact the semiconductor layer 110 through the one or more vias 108.

In an aspect, the semiconductor device 100 may include one or more top electrodes 112. The one or more top electrodes 112 may include indium tin oxide, aluminum doped zinc oxide, fluorine doped tin oxide, silver, gold, aluminum, or other electrodes.

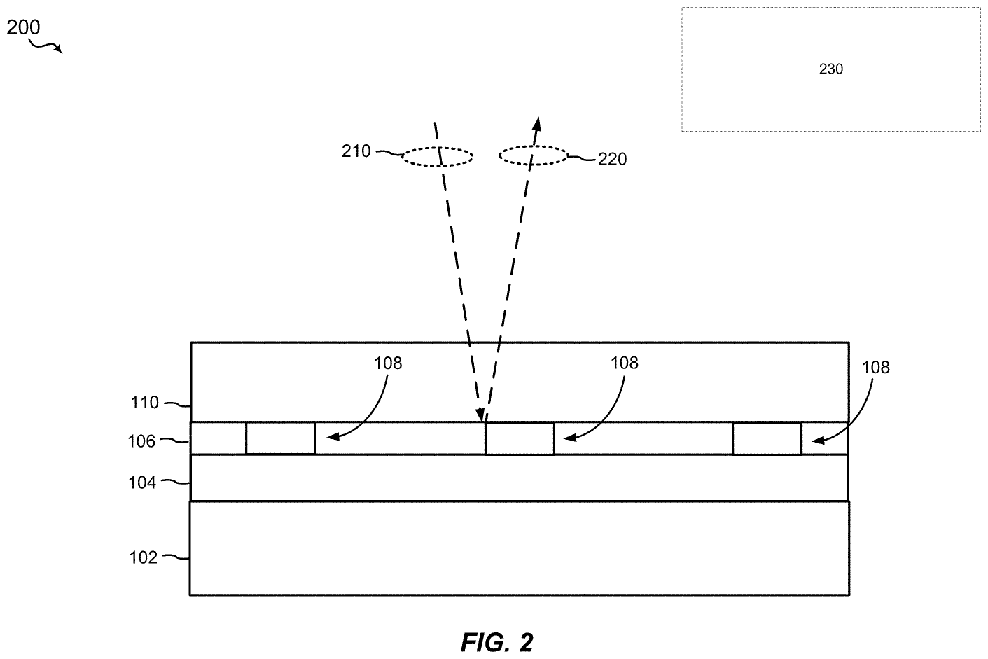

Turning now to FIG. 2, according to an aspect of the present disclosure, an incident light 210 (having a wavelength longer than a wavelength of a light correspond to the bandgap of the semiconductor layer 110) may be illuminated onto the semiconductor device 100 during an alignment process and cause a reflected light 220 off of the carrier 102, the one or more bottom electrodes 104, and/or the dielectric layer 106. The incident light 210 having a wavelength longer than the wavelength of the light correspond to the bandgap of the semiconductor layer 110 may be referred to as the sub-bandgap light. The sub-bandgap light may have a wavelength longer than a light absorbable or emittable by the semiconductor layer 110. The semiconductor layer 110 may be transparent to the incident light 210. In some examples, the semiconductor layer 110 may be unable or nearly unable to absorb the incident light 210. In other example, the semiconductor layer 110 may absorb a small percentage of the incident light 210, such as 5 percent, 3 percent, 1 percent, 0.1 percent, 1×10⁻² percent, 1×10⁻³ percent, or lower.

In some implementations, the alignment process may be implemented to align the one or more top electrodes 112 to the one or more bottom electrodes 104. By using a sub-bandgap light, the incident light 210 may penetrate the semiconductor layer 110 and be reflected off of the carrier 102, the one or more bottom electrodes 104, and/or the dielectric layer 106.

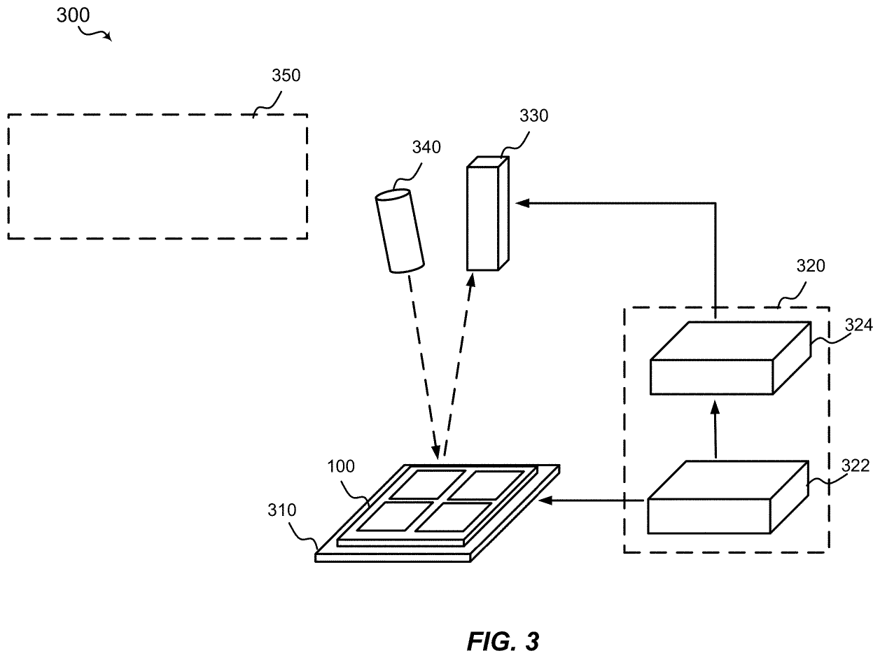

Referring now to FIG. 3, in some implementations, an alignment system 300 may include a stage 310, a control system 320, a detector 330, one or more light sources 340 and optional deposition system 350. The stage 310 may include linear actuators and rotational actuators (e.g., servomotor) to control the vertical and horizontal translations and angular rotation of the stage 310. The control system 320 may include a stage controller 322 for transmitting signals, commands, and/or instructions to the stage 310 to control the translations and rotation of the stage 310. The control system 320 may include an optical controller 324 to control the detector 330 and/or the one or more light sources 340. The optical controller 324 may transmit signals, commands, and/or instructions to alter the output intensity of the one or more light sources 340, the incident angle of the incident light 210 (by changing the tilt of the one or more light sources 340, for example) and vertical and horizontal translations and angular rotation of the one or more light sources 340. The optical controller 324 may control the focus, sensitivity, field (dark or bright), or detection parameters of the detector 330. The optical controller 324 may detect patterns on the surface of the semiconductor device 100. The optical controller 324 may include image processing capabilities to identify a contour, an outline, a delineation, a shape, an array, a pattern, or a border of the carrier 102, the plurality of bottom electrodes 104, the dielectric layer 106, and the plurality of vias 108. In some examples, the contour, outline, delineation, shape, array, pattern or border of the plurality of vias 108 may include adjacent and/or consecutive vias of the plurality of vias 108. In other examples, the contour, outline, delineation, shape, array, pattern or border of the plurality of bottom electrodes 104 may include adjacent and/or consecutive electrodes of the plurality of bottom electrodes 104. The optical controller 324 may be able to process both bright-field and dark-field images.

Still referring to FIG. 3, during normal operations, the one or more light sources 340 of the alignment system 300 may emit the incident light 210 toward the semiconductor device 100. The incident light 210 may be a sub-bandgap light. For example, the wavelength of the incident light 210 may be 600 nanometers (nm), 700 nm, 800 nm, 900 nm, 1 micrometer (μm), 2 μm, 5 μm, 10 μm, 20 μm, 50 μm, 100 μm, 200 μm, 500 μm, or 1 millimeter (mm). Other wavelengths are possible. The semiconductor layer 110 may be transparent or substantially transparent to the sub-bandgap light. The incident light 210 may reflect off the carrier 102, the one or more bottom electrodes 104, the dielectric layer 106, the one or more vias 108, or a combination thereof. The reflected incident light 210 may become the reflected light 220. The reflected light 220 may be detected by the detector 330.

In certain aspects, the detector 330 may receive the reflected light 220 to detect patterns on the semiconductor device 100. The detector 330 may detect light having a wavelength of 600 nm, 700 nm, 800 nm, 900 nm, 1 μm, 2 μm, 5 μm, 10 μm, 20 μm, 50 μm, 100 μm, 200 μm, 500 μm, or 1 mm. In one example, the detector 330 may perform alignment based on a feature, such as a pattern or an edge, on the semiconductor device 100. The detected feature may be detected because the incident light 210 reflects off of the carrier 102, the one or more bottom electrodes 104, the dielectric layer 106, and/or the one or more vias 108. The detector 330 may detect the feature underneath the semiconductor layer 110.

In some implementations, the detected feature, such as the pattern or the edge, may include a number of components, such as the one or more bottom electrodes 104 and the one or more vias 108. The number of components may be 1000, 10000, 100000, or more. The detected feature used for alignment may be macroscopic (e.g., visible to the naked eye). In some examples, the detected feature may be 1 mm, 5 mm, 1 centimeter (cm), 2 cm, 5 cm, 10 cm, 20 cm, or larger. The detected feature may range from 1 mm to 100 cm, or 1 cm to 10 cm, 2 cm to 8 cm, or 4 cm to 6 cm. The alignment process may not require a high magnification detector.

In certain aspects, the detected feature may include the one or more bottom electrodes 104 and/or the one or more vias 108 may be engineered to reflect the incident light 210. For example, a portion of the sidewall of the one or more vias 108 may be rounded to improve reflection of the incident light 210 at various angles. The rounded sidewall of the one or more vias 108 may improve the detection of the structures and allow for more reliable alignment.

In some aspects, prior to the alignment process, a pre-alignment process may be performed. In the pre-alignment process, the carrier 102 may be aligned to one or more marks on the stage 310. For example, one or more edges of the carrier 102 may be aligned to corresponding marks on the stage 310. The pre-alignment process may be performed using the incident light 210 or visible lights.

In some implementations, the deposition system 350 may be integrated with the alignment system 300. The deposition system 350 may be configured to deposit metal, insulators, semiconductors, or other materials. The deposition system 350 may be a metal-oxide chemical vapor deposition (MOCVD) system, a sputter, an evaporator, an atomic layer deposition, a chemical vapor deposition (CVD) system, a plasma enhanced chemical vapor deposition (PECVD) system, a pulsed laser ablation (PLA), or other systems.

In other implementations, the alignment system 300, with or without the optional deposition system 350, may be integrated with a printing system (e.g., screen printing, inkjet printing, 3D printing, etc.), a cutting system (e.g., dicing, laser cutting, waterjet cutting, etc.), an etching system (e.g., dry etching, wet etching), and a probing system.

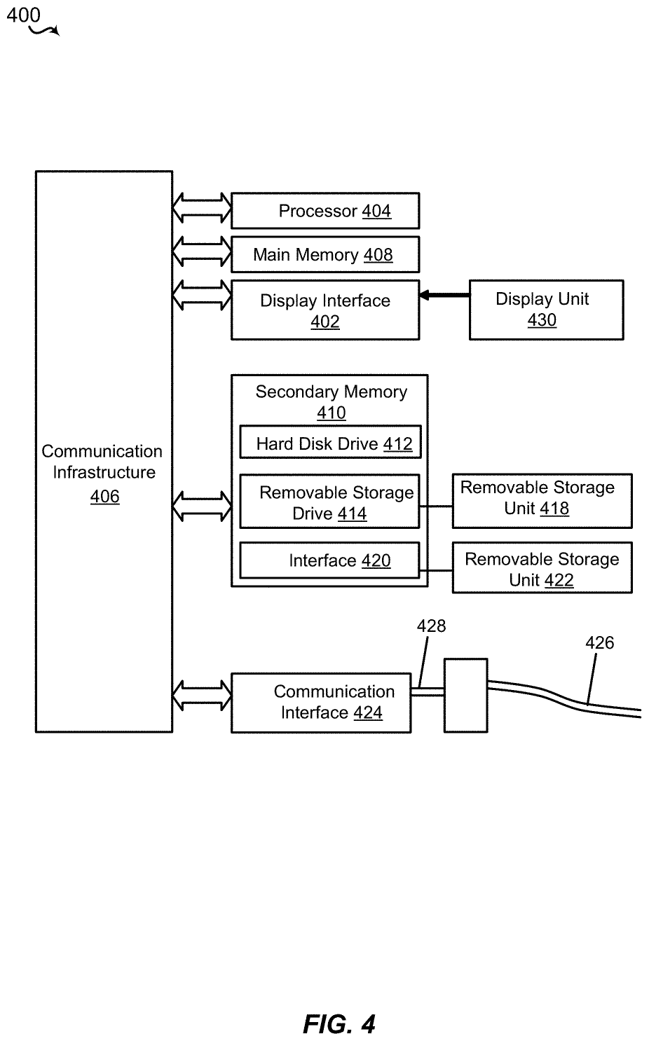

Referring now to FIG. 4, the control system 320 may be implemented as an example of a computer system 400. The computer system 400 may be a hardware system, a virtual system, a cloud-based system, or a combination thereof. The computer system 400 includes one or more processors, such as the processor 404. The processor 404 is communicatively coupled with a communication infrastructure 406 (e.g., a communications bus, cross-over bar, or network).

The computer system 400 may include a display interface 402 that forwards graphics, text, and other data from the communication infrastructure 406 (or from a frame buffer not shown) for display on a display unit 430. Computer system 400 also includes a main memory 408, preferably random access memory (RAM), and may also include a secondary memory 410. The secondary memory 410 may include, for example, a hard disk drive 412, and/or a removable storage drive 414, representing a floppy disk drive, magnetic tape drive, optical disk drive, universal serial bus (USB) flash drive, etc. The removable storage drive 414 reads from and/or writes to a first removable storage unit 418 in a well-known manner. The first removable storage unit 418 represents a floppy disk, magnetic tape, optical disk, USB flash drive etc., which is read by and written to removable storage drive 414. As will be appreciated, the first removable storage unit 418 includes a computer usable storage medium having stored therein computer software and/or data.

Alternative aspects of the present disclosure may include secondary memory 410 and may include other similar devices for allowing computer programs or other instructions to be loaded into computer system 400. Such devices may include, for example, a second removable storage unit 422 and an interface 420. Examples of such may include a program cartridge and cartridge interface (such as that found in video game devices), a removable memory chip (such as an erasable programmable read only memory (EPROM), or programmable read only memory (PROM)) and associated socket, and other removable storage units (not shown) and interfaces 420, which allow software and data to be transferred from the second removable storage unit 422 to computer system 400.

Computer system 400 may also include a communications interface 424. Communications interface 424 allows software and data to be transferred between computer system 400 and external devices. Examples of communications interface 424 may include a modem, a network interface (such as an Ethernet card), a communications port, a Personal Computer Memory Card International Association (PCMCIA) slot and card, etc. Software and data transferred via communications interface 424 are in the form of signals 428, which may be electronic, electromagnetic, optical or other signals capable of being received by communications interface 424. These signals 428 are provided to communications interface 424 via a communications path (e.g., channel) 426. This path 426 carries signals 428 and may be implemented using one or more of a wire or cable, fiber optics, telephone line, cellular link, RF link and/or other communications channels. In this document, the terms “computer program medium” and “computer usable medium” are used to refer generally to media such as the first removable storage drive 418, a hard disk installed in hard disk drive 412, and signals 428. These computer program products provide software to the computer system 400. Aspects of the present disclosure are directed to such computer program products.

Computer programs (also referred to as computer control logic) are stored in main memory 408 and/or secondary memory 410. Computer programs may also be received via communications interface 424. Such computer programs, when executed, enable the computer system 400 to perform the features in accordance with aspects of the present disclosure, as discussed herein. In particular, the computer programs, when executed, enable the processor 404 to perform the features in accordance with aspects of the present disclosure. Accordingly, such computer programs represent controllers of the computer system 400.

In an aspect of the present disclosure where the method is implemented using software, the software may be stored in a computer program product and loaded into computer system 400 using removable storage drive 414, hard drive 412, or communications interface 420. The control logic (software), when executed by the processor 404, causes the processor 404 to perform the functions described herein. In another aspect of the present disclosure, the system is implemented primarily in hardware using, for example, hardware components, such as application specific integrated circuits (ASICs). Implementation of the hardware state machine so as to perform the functions described herein will be apparent to persons skilled in the relevant art(s).

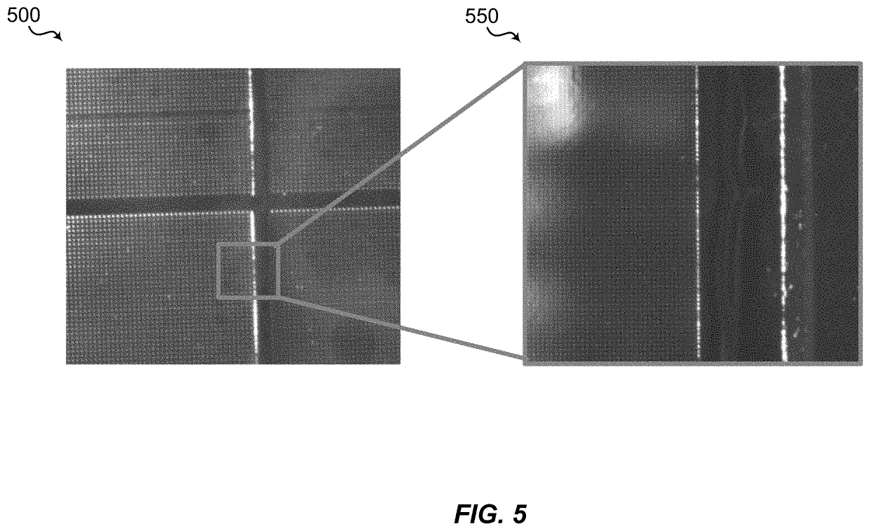

Referring now to FIG. 5, an example of an image 500 detected by the detector 330 may be a top view of the semiconductor device 100 when the semiconductor device 100 is illuminated by the incident light 210. A magnified image 550 of the image 500 may show an edge, caused by the incident light 210 reflecting off of materials in or around the one or more vias 108. The edge may be detected by the detector 300 and identified by the optical controller 324. The optical controller 324 may utilize the edge to perform alignment. By using the one or more bottom electrodes 104 or the one or more vias 108, which are part of a semiconductor structure, such as a solar cell, the alignment process may include lower misalignment and thus higher yield, for example, due to reduced offset. In some implementations, the optical controller 324 may rely on one or more edges and/or intersections among devices for alignment.

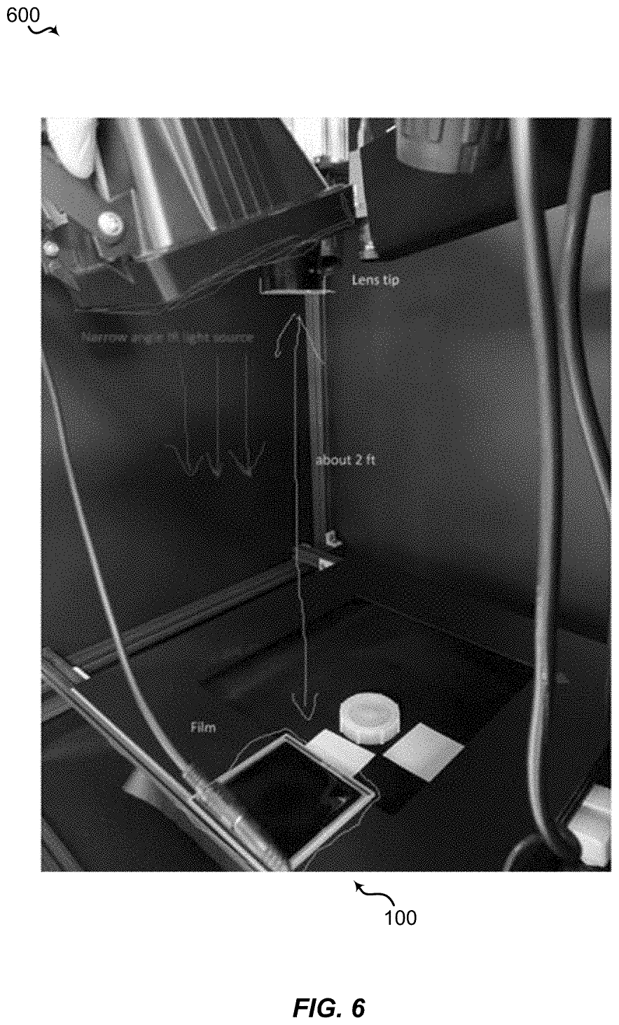

Referring to FIG. 6, an example of the alignment system 600 and the semiconductor device 100 is shown. A camera is at the top of the alignment system 600, facing downward toward the semiconductor device 100. While the camera is disposed approximately 2 feet from the semiconductor device 100, the length may vary based on various arrangements, including the camera field of view or the camera resolution. A light source is at the top-left of the alignment system 600. The light source may be sub-bandgap light.

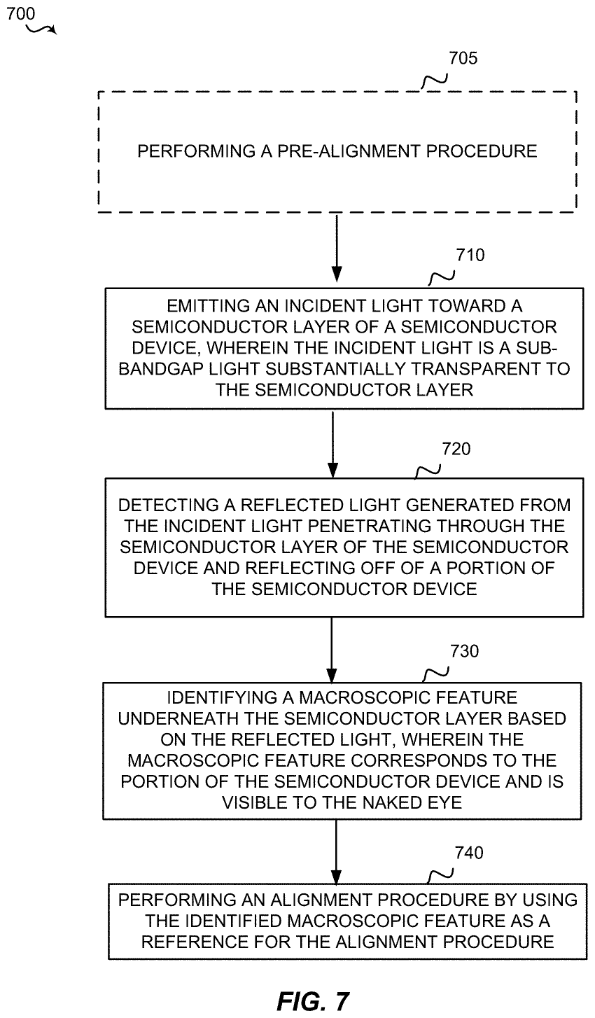

Referring to FIG. 7, an example of a method 700 for performing alignment may include using a sub-bandgap light for illumination.

At block 705, in some implementations, the method 700 may optionally perform a pre-alignment procedure. The pre-alignment procedure may include aligning the substrate 102 (e.g., one or more edges) to the stage 310 (e.g., markers).

At block 710, the method 700 may emit an incident light toward a semiconductor layer of a semiconductor device, wherein the incident light is a sub-bandgap light. For example, the optical controller 324 may cause the one or more light sources 340 to emit an incident light 210 (such as a sub-bandgap light) toward the semiconductor layer 110 of the semiconductor device 100.

At block 720, the method 700 may detect a reflected light generated from the incident light penetrating through the semiconductor layer of the semiconductor device and reflecting off of a portion of the semiconductor device. For example, the detector 330 may detect the reflected light 220 from the incident light 210 penetrating through the semiconductor layer 110 and reflecting off of the carrier 102, the one or more bottom electrodes 104, the dielectric layer 106, and/or the one or more vias 108.

At block 730, the method 700 may identify a macroscopic feature underneath the semiconductor layer based on the reflected light. For example, the optical controller 324 may identify a macroscopic feature underneath the semiconductor layer 110 based on the reflected light 220, such as a pattern or an edge larger than 1 mm, 5 mm, 1 cm, 2 cm, 5 cm, 10 cm, or 20 cm.

At block 740, the method 700 may perform an alignment procedure based on the identified macroscopic feature. For example, the alignment system 300 may perform an alignment procedure, in conjunction with the stage controller 322 controlling the stage 310, based on the identified macroscopic feature.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, computer-executable code or instructions stored on a computer-readable medium, or any combination thereof.

The various illustrative blocks and components described in connection with the disclosure herein may be implemented or performed with a specially-programmed device, such as but not limited to a processor, a digital signal processor (DSP), an ASIC, a FPGA or other programmable logic device, a discrete gate or transistor logic, a discrete hardware component, or any combination thereof designed to perform the functions described herein. A specially-programmed processor may be a microprocessor, but in the alternative, the processor may be any conventional processor, controller, microcontroller, or state machine. A specially-programmed processor may also be implemented as a combination of computing devices, e.g., a combination of a DSP and a microprocessor, multiple microprocessors, one or more microprocessors in conjunction with a DSP core, or any other such configuration.

The functions described herein may be implemented in hardware, software executed by a processor, firmware, or any combination thereof. If implemented in software executed by a processor, the functions may be stored on or transmitted over as one or more instructions or code on a non-transitory computer-readable medium. Other examples and implementations are within the scope and spirit of the disclosure and appended claims. For example, due to the nature of software, functions described above may be implemented using software executed by a specially programmed processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C).

Computer-readable media includes both computer storage media and communication media including any medium that facilitates transfer of a computer program from one place to another. A storage medium may be any available medium that may be accessed by a general purpose or special purpose computer. By way of example, and not limitation, computer-readable media may comprise RAM, ROM, EEPROM, CD-ROM or other optical disk storage, magnetic disk storage or other magnetic storage devices, or any other medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The previous description of the disclosure is provided to enable a person skilled in the art to make or use the disclosure. Various modifications to the disclosure will be readily apparent to those skilled in the art, and the common principles defined herein may be applied to other variations without departing from the spirit or scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

1. A method of alignment, comprising:
emitting an incident light toward a semiconductor layer of a semiconductor device, wherein the incident light is a sub-bandgap light substantially transparent to the semiconductor layer;
detecting a reflected light generated from the incident light penetrating through the semiconductor layer of the semiconductor device and reflecting off of a portion of the semiconductor device;
identifying a macroscopic feature underneath the semiconductor layer based on the reflected light, wherein the macroscopic feature corresponds to the portion of the semiconductor device and is visible to the naked eye; and
performing an alignment procedure by using the identified macroscopic feature as a reference for the alignment procedure.

2. The method of claim 1, further comprising performing one or more processing steps on the semiconductor device after performing the alignment procedure, the one or more processing steps including one or more deposition steps, one or more printing steps, one or more cutting steps, one or more etching steps, one or more probing steps, or a combination thereof.

3. The method of claim 1, wherein performing an alignment procedure further includes maintaining a detector that detects the reflected light stationary in relation to a stage having the semiconductor device.

4. The method of claim 1, wherein the incident light has a center wavelength longer than 1000 nm.

5. The method of claim 1, wherein the semiconductor layer includes at least one of gallium arsenide, gallium arsenide phosphide, gallium phosphide, aluminum gallium arsenide, aluminum gallium nitride, aluminum gallium indium phosphide, aluminum gallium indium nitride, aluminum gallium, aluminum phosphide, aluminum nitride, zinc selenide, indium gallium nitride, indium gallium arsenide, or silicon carbide.

6. The method of claim 1, wherein the semiconductor device further includes at least one of a carrier, a plurality of bottom electrodes, a dielectric layer, or a plurality of vias.

7. The method of claim 1, wherein the macroscopic feature includes at least one of a contour, an outline, a delineation, a shape, an array, a pattern, or a border of at least one of a carrier, a plurality of bottom electrodes, a dielectric layer, and a plurality of vias in the semiconductor device.

8. The method of claim 1, wherein the plurality of vias includes two or more adjacent vias.

9. The method of claim 1, wherein the macroscopic feature is larger than 1 centimeter.

10. The method of claim 1, wherein the macroscopic feature is a linear feature larger than 1 millimeter or a combination of linear features larger than 1 millimeter.

11. The method of claim 1, further comprises performing a pre-alignment procedure prior to emitting the incident light.

12. The method of claim 1, wherein detecting the reflected light further comprises detecting the incident light reflected off of a plurality of sidewalls of a plurality of vias.

13. An alignment system, comprising:
a stage;
one or more light sources configured to emit an incident light toward a semiconductor layer of a semiconductor device positioned on the stage, wherein the incident light is a sub-bandgap light substantially transparent to the semiconductor layer;
a detector configured to detect a reflected light generated from the incident light penetrating through the semiconductor layer of the semiconductor device and reflecting off of a portion of the semiconductor device;
an optical controller configured to identify a macroscopic feature underneath the semiconductor layer based on the reflected light, wherein the macroscopic feature corresponds to the portion of the semiconductor device and is visible to the naked eye; and
a stage controller configured to perform an alignment procedure by using the identified macroscopic feature as a reference for the alignment procedure.

14. The alignment system of claim 13, a deposition system configured to perform one or more processing steps on the semiconductor device after performing the alignment procedure, the one or more processing steps including one or more deposition steps, one or more printing steps, one or more cutting steps, one or more etching steps, one or more probing steps, or a combination thereof.

15. The alignment system of claim 13, wherein the stage controller is further configured to perform the alignment procedure by maintaining the detector stationary in relation to the stage having the semiconductor device.

16. The alignment system of claim 13, further comprising at least one of a linear actuator for translating the stage or a rotational actuator for rotating the stage.

17. The alignment system of claim 13, wherein the one or more light sources are further configured to emit the incident light having a center wavelength longer than 1000 nanometer.

18. The alignment system of claim 13, wherein the detector is further configured to detect the reflected light having a wavelength longer than 1000 nanometer.

19. A system for alignment, comprising:
means for emitting an incident light toward a semiconductor layer of a semiconductor device, wherein the incident light is a sub-bandgap light substantially transparent to the semiconductor layer;
means for detecting a reflected light generated from the incident light penetrating through the semiconductor layer of the semiconductor device and reflecting off of a portion of the semiconductor device;
means for identifying a macroscopic feature underneath the semiconductor layer based on the reflected light, wherein the macroscopic feature corresponds to the portion of the semiconductor device and is visible to the naked eye; and
means for performing an alignment procedure by using the identified macroscopic feature as a reference for the alignment procedure.

20. The method of claim 19, wherein means for performing an alignment procedure further includes means for translating or rotating a stage having the semiconductor device.

21-23. (canceled)
